(19) United States
(12) Patent Application Publication
(10) Pub. No.: US 2016/0087004 A1
(43) Pub. Date: Mar. 24, 2016

(54) MAGNETIC MEMORY AND METHOD OF MANUFACTURING THE SAME

(71) Applicants: Yasuyuki SONODA, Seoul (KR); Min Suk LEE, Seongnam-si Gyeonggi-do (KR); Ji Hwan HWANG, Dongjak-gu Seoul (KR); Chang Hyup SHIN, Yongin-si Gyeonggi-do (KR); Masatoshi YOSHIKAWA, Seoul (KR)

(72) Inventors: Yasuyuki SONODA, Seoul (KR); Min Suk LEE, Seongnam-si Gyeonggi-do (KR); Ji Hwan HWANG, Dongjak-gu Seoul (KR); Chang Hyup SHIN, Yongin-si Gyeonggi-do (KR); Masatoshi YOSHIKAWA, Seoul (KR)

(21) Appl. No.: 14/635,920

(22) Filed: Mar. 2, 2015

Related U.S. Application Data
(60) Provisional application No. 62/052,328, filed on Sep. 18, 2014.

(51) Int. Cl. H01L 27/22; G11C 11/16; H01L 43/12; H01L 43/02; H01L 43/08

(52) U.S. Cl. CPC H01L 27/228; H01L 43/02; H01L 43/08; H01L 43/12; G11C 11/161

(57) ABSTRACT

According to one embodiment, a magnetic memory includes a magnetic element, and a metal layer stacked on the magnetic element. H/D>1.47 is satisfied, where H denotes a sum of thicknesses of the magnetic element and the metal layer in a first direction in which the magnetic element and the metal layer are stacked, and D denotes a width of the magnetic element in a second direction perpendicular to the first direction.

### CROSS-REFERENCE TO RELATED APPLICATIONS

This application claims the benefit of U.S. Provisional Application No. 62/052,328, filed Sep. 18, 2014, the entire contents of which are incorporated herein by reference.

### FIELD

Embodiments described herein relate generally to a magnetic memory and a method of manufacturing the same.

### BACKGROUND

In recent years, various kinds of devices comprising magnetic elements have been developed. A magnetic memory, which is one of these, for example a spin-transfer-torque (STT)-magnetic random access memory (MRAM), stores data in a magnetic element.

In these devices, the patterning of a magnetic element is performed by physical etching such as ion beam etching (IBE) with a metal layer as a hard mask used as a mask. However, the physical etching has a problem that it is hard to sufficiently increase an etching selection ratio between the magnetic element and the hard mask.

### BRIEF DESCRIPTION OF THE DRAWINGS

FIG. 1 is an illustration showing an etching method as an embodiment;

FIG. 2 is an illustration showing an etching method as a comparative example;

FIG. 3 is an illustration explaining an effect of remaining/removing of a mask layer;

FIG. 4 is an illustration showing a memory cell of an MRAM as an application example;

FIG. 5 is a sectional view taken along line V-V of FIG. 4;

FIG. 6 a sectional view taken along line VI-VI of FIG. 4;

FIG. 7 is an illustration showing an aspect ratio of a magnetic element;

FIG. 8 and FIG. 9 are illustrations showing a relationship between an acceleration voltage and the aspect ratio;

FIG. 10 to FIG. 12 are illustrations showing an example of a method of manufacturing a magnetoresistive effect element;

FIG. 13 is an illustration showing an example of an IBE apparatus; and

FIG. 14 is an illustration showing an example of a grid.

### DETAILED DESCRIPTION

In general, according to one embodiment, a magnetic memory comprises: a magnetic element; and a metal layer stacked on the magnetic element, wherein H/D>1.47 is satisfied, where H denotes a sum of thicknesses of the magnetic element and the metal layer in a first direction in which the magnetic element and the metal layer are stacked, and D denotes a width of the magnetic element in a second direction perpendicular to the first direction.

### 1. Embodiment

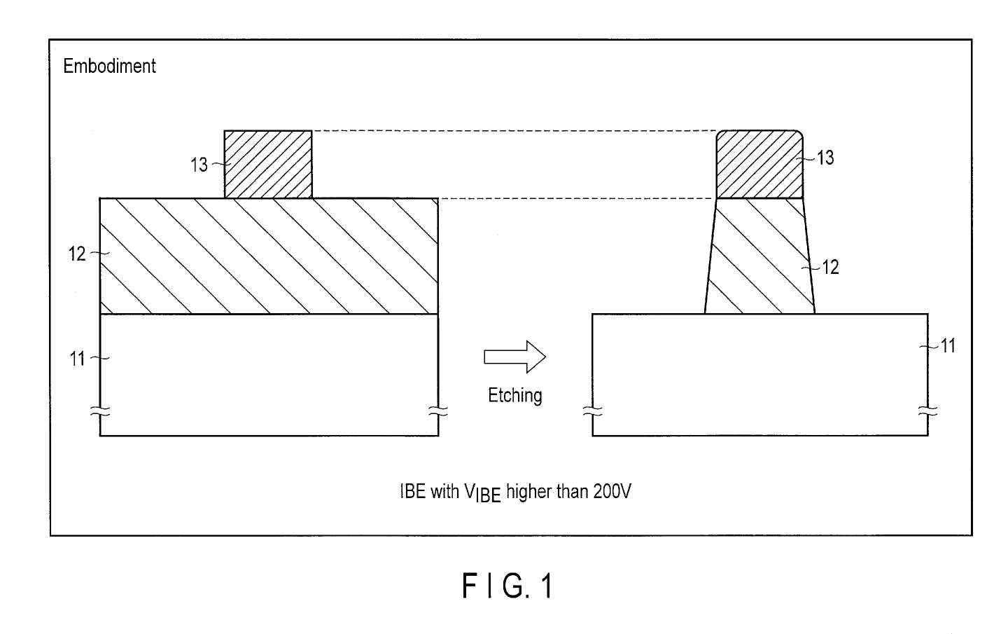

FIG. 1 shows an etching method as an embodiment.

In the embodiment, first, a magnetic layer 12 is formed on a substrate 11, and a metal layer 13 is formed on the magnetic layer 12. In addition, the metal layer 13 is patterned by a photo-engraving process (PEP) and reactive ion etching (RIE). The metal layer 13 may be patterned by ion beam etching (IBE) instead of by RIE.

Then, with the metal layer 13 used as a mask, the magnetic layer 12 is patterned by IBE. This IBE is executed by using an ion beam accelerated by an acceleration voltage higher than 200 V. The ion beam includes one of Ne, Ar, Kr, Xe, N₂ and O₂.

According to the embodiment, the acceleration voltage of the ion beam is set at a value higher than 200 V. In this case, the etching rate of the magnetic layer 12 increases more with respect to the etching rate of the metal layer 13 than in the case where the acceleration voltage of the ion beam is 200 V. That is, an etching selection ratio between the magnetic layer 12 and the metal layer 13 can be improved.

This is caused for the following reasons:

The irradiation of an ion beam exhibits an etching effect or an ion implantation effect on an object to which the ion beam is irradiated. In the case of the embodiment, as the acceleration voltage of an ion beam becomes larger, the etching effect becomes larger in the magnetic layer 12, while the ion implantation effect becomes larger in the metal layer 13. Thus, it is conceivable that such an advantage of an improvement in an etching selection ratio as described above can be obtained.

It should be noted that the above-described advantage can be obtained from a magnetic material including Co, Fe, Tb, etc., with respect to the magnetic layer 12, and from a metal material including W, Ta, Ru, Ti, TaN, TiN, etc., with respect to the metal layer 13. In addition, the magnetic layer 12 may have a single-layer structure or may have a multilayer structure.

Moreover, if the magnetic layer 12 is thick, for example, if the magnetic layer 12 has a multilayer structure, it is preferable to pattern the magnetic layer 12 by first etching and second etching after the first etching in order to prevent a bad influence of an etched material generated incidentally by IBE.

The first etching is executed at a beam angle selected to be in the range of, for example, 30° to 89°, and more preferably in the range of 30° to 60°, and the second etching is executed at a beam angle selected to be in the range of, for example, 0° to 30°. However, the beam angles are angles between a direction in which the magnetic layer 12 and the metal layer 13 are stacked and a direction in which an ion beam is irradiated.

Also in this case, the first and second etchings are executed by using an ion beam accelerated by an acceleration voltage higher than 200 V.

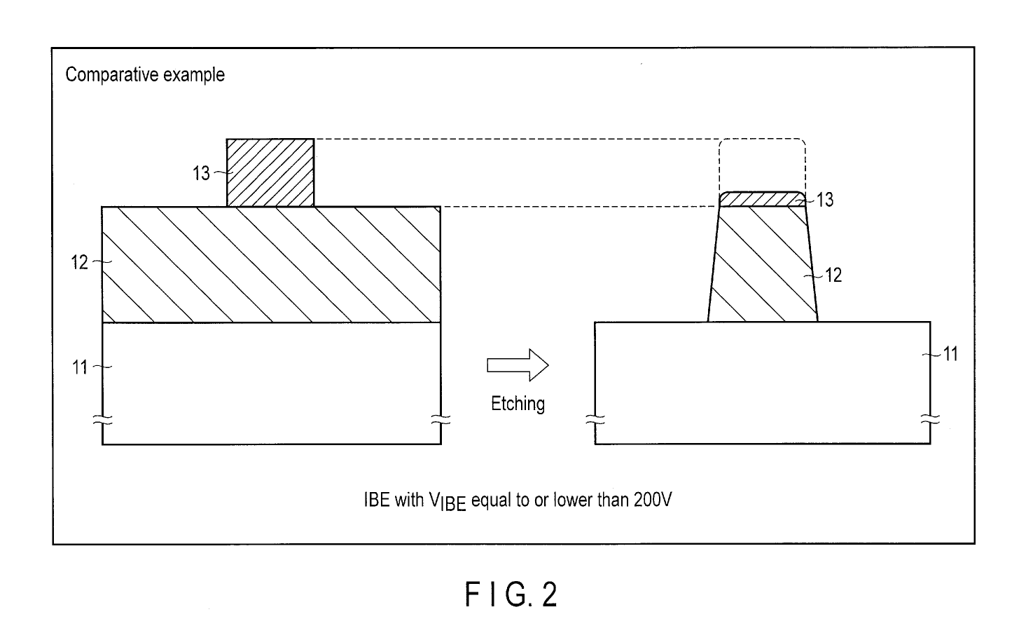

FIG. 2 shows an etching method as a comparative example.

The comparative example (FIG. 2) differs from the embodiment (FIG. 1) only in acceleration voltage of an ion beam. That is, in the comparative example, the acceleration voltage of an ion beam used for IBE is set at 200 V or a value lower than 200 V. The other points are the same as in the embodiment.

In the comparative example, first, the magnetic layer 12 is formed on the substrate 11, and the metal layer 13 is formed on the magnetic layer 12. In addition, the metal layer 13 is patterned by PEP and RIE. The metal layer 13 may be patterned by IBE instead of by RIE.

Then, with the metal layer 13 used as a mask, the magnetic layer 12 is patterned by IBE. This IBE is executed by using an ion beam accelerated by an acceleration voltage of 200 V or a value lower than 200 V. The ion beam includes one of Ne, Ar, Kr, Xe, N₂ and O₂.

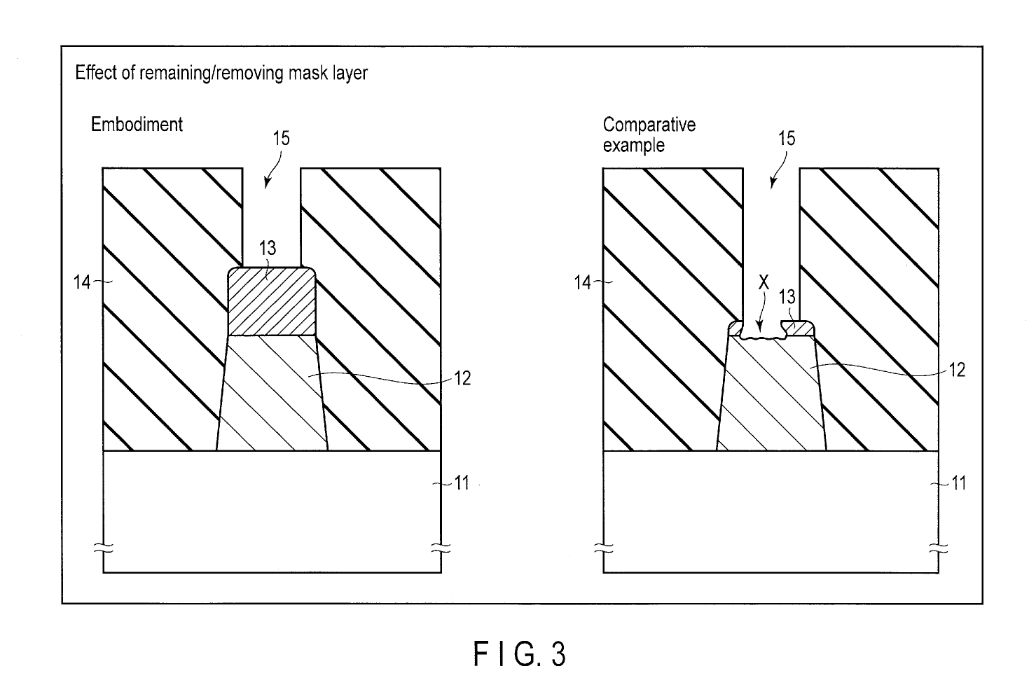

In the case of the comparative example, as shown in FIG. 3, a damage may occur to the magnetic layer 12 when a contact hole 15 is formed in an interlayer insulating layer 14. This is caused by the thinness of the metal layer 13. For example, when the contact hole 15 is formed by RIE, the metal layer 13 as a stopper is etched and the magnetic layer 12 may also be partly etched. In this case, when cleaning is done in the contact hole 15 by a wet process, a chemical solution may corrode the magnetic layer 12 and the metal layer 13.

For the above reason, it is preferable to make the metal layer 13 as thick as possible. According to the embodiment, because the etching selection ratio between the magnetic layer 12 and the metal layer 13 can be improved, the metal layer 13, which is sufficiently thick, can be secured even after a magnetic element is patterned.

### 2. Application Example

A magnetic memory as an application example will be described.

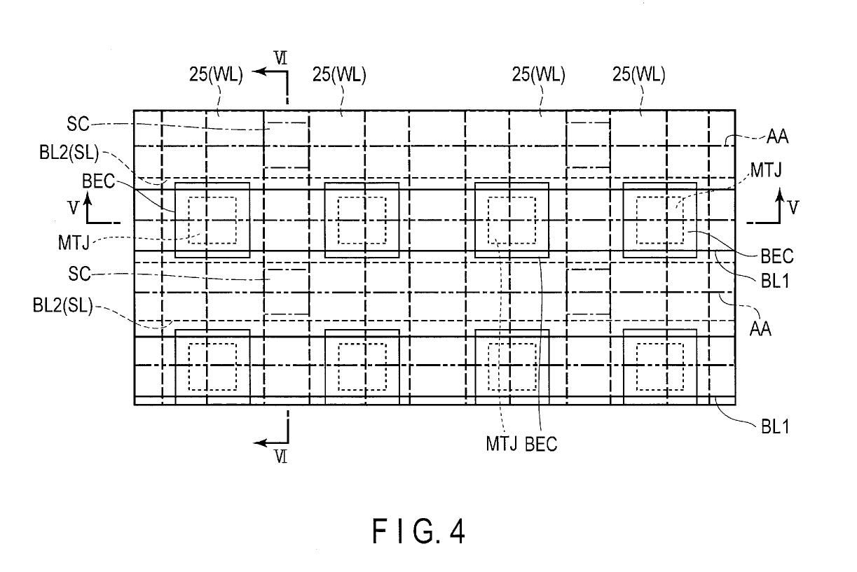

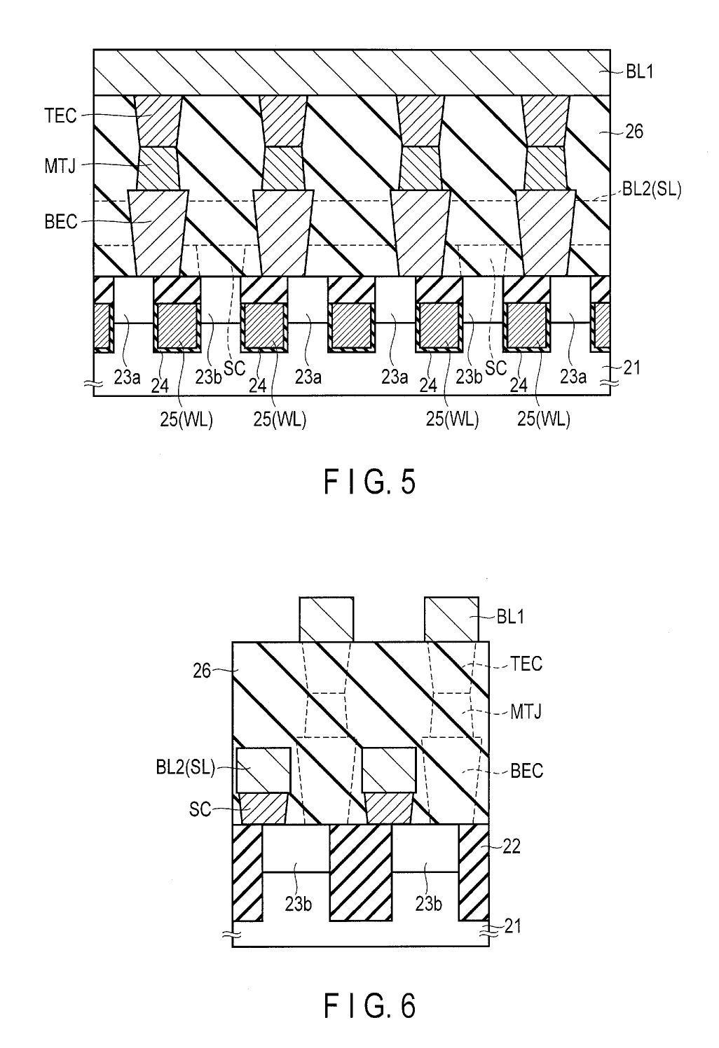

FIG. 4 to FIG. 6 show a memory cell of an MRAM as the application example. FIG. 4 is a plan view of the memory cell of the MRAM, FIG. 5 is a sectional view taken along line V-V of FIG. 4, and FIG. 6 is a sectional view taken along line VI-VI of FIG. 4.

In the example, the memory cell of the magnetic memory comprises a selection transistor (for example, an FET) ST and a magnetoresistive effect element MTJ.

The selection transistor ST is disposed in an active area AA in a semiconductor substrate 21. The active area AA is surrounded by an element isolation insulating layer 22 in the semiconductor substrate 21. In the example, the element isolation insulating layer 22 has a shallow trench isolation (STI) structure.

The selection transistor ST comprises source/drain diffusion layers 23a and 23b in the semiconductor substrate 21, and a gate insulating layer 24 and a gate electrode (word line) 25 formed therebetween in the semiconductor substrate 21. The selection transistor ST of the example has a so-called embedded gate structure in which the gate electrode 25 is embedded in the semiconductor substrate 21.

An interlayer insulating layer (for example, a silicon oxide layer) 26 covers the selection transistor ST. Contact plugs BEC and SC are disposed in the interlayer insulating layer 26. The contact plug BEC is connected to the source/drain diffusion layer 23a, and the contact plug SC is connected to the source/drain diffusion layer 23b. The contact plugs BEC and SC include, for example, one of W, Ta, Ru and Ti.

The magnetoresistive effect element MTJ is disposed on the contact plug BEC. In addition, a contact plug TEC is disposed on the magnetoresistive effect element MTJ.

A bit line BL1 is connected to the magnetoresistive effect element MTJ through the contact plug TEC. A bit line BL2 is connected to the source/drain diffusion layer 23b through the contact plug SC. The bit line BL2 also functions as, for example, a source line SL to which ground potential is applied at the time of reading.

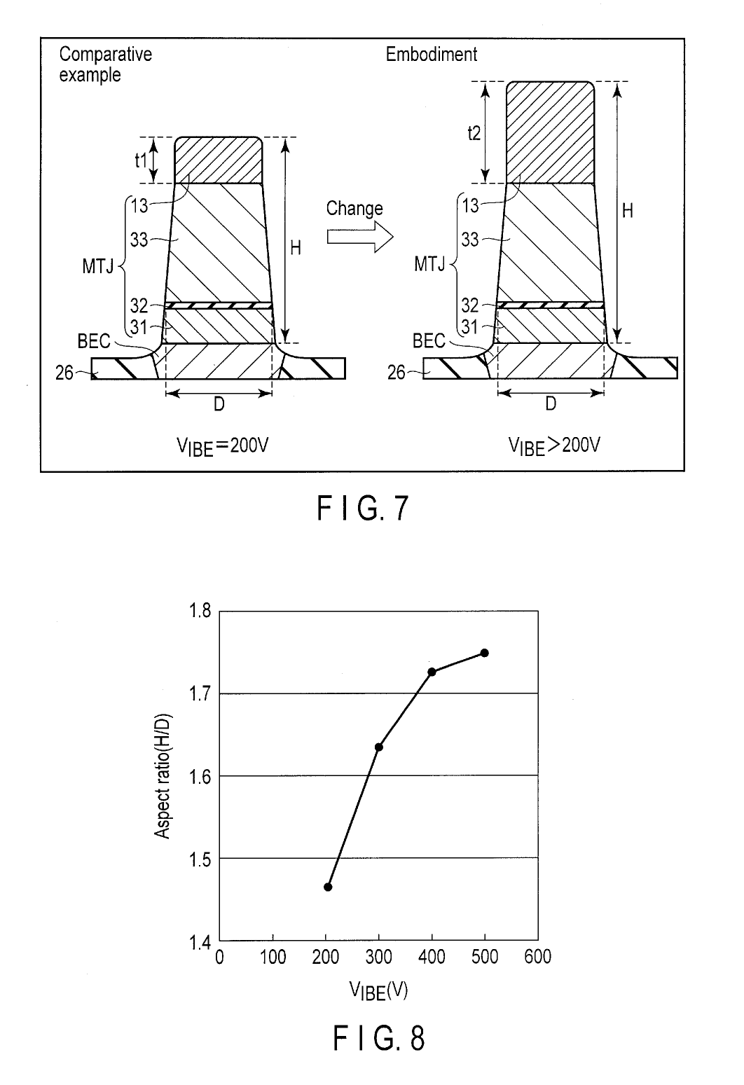

FIG. 7 shows an example of the magnetoresistive effect element MTJ of FIG. 4 to FIG. 6.

In the figure, the same elements as those shown in FIG. 4 to FIG. 6 are given the same numbers.

The magnetoresistive effect element MTJ comprises a first ferromagnetic layer 31 on the contact plug BEC, a nonmagnetic insulating layer (tunnel barrier layer) 32 on the first ferromagnetic layer 31, a second ferromagnetic layer 33 on the nonmagnetic insulating layer 32, and the hard mask layer 13 on the second ferromagnetic layer 33.

The hard mask layer 13 functions as, for example, a mask layer at the time of processing the magnetoresistive effect element MTJ. The hard mask layer 13 includes, for example, W, Ta, Ru, Ti, TaN or TiN. It is preferable that the hard mask layer 13 comprise a material which has a low electrical resistance and good diffusion, etching and milling tolerances, for example, a lamination of Ta/Ru.

One of the first and second ferromagnetic layers 31 and 33 is a reference layer having invariable magnetization, and the other is a storage layer having variable magnetization.

Here, the invariable magnetization means that a magnetization direction does not vary before or after writing, and the variable magnetization means that the magnetization direction can vary in reverse before or after writing.

Further, the writing means spin transfer writing in which a spin implantation current (spin-polarized electron) is passed to the magnetoresistive element MTJ, thereby imparting a spin torque to the magnetization of a storage layer.

If the first ferromagnetic layer 31 is a storage layer and the second ferromagnetic layer 33 is a reference layer, the magnetoresistive effect element MTJ is referred to as a top-pin type. In addition, if the first ferromagnetic layer 31 is a reference layer and the second ferromagnetic layer 33 is a storage layer, the magnetoresistive effect element MTJ is referred to as a bottom-pin type.

It is preferable that each of the first and second ferromagnetic layers 31 and 33 have vertical magnetization, that is, residual magnetization in a vertical direction in which the first and second ferromagnetic layers 31 and 33 are stacked. However, each of the first and second ferromagnetic layers 31 and 33 may have in-plane magnetization, that is, residual magnetization in an in-plane direction perpendicular to a direction in which the first and second ferromagnetic layers 31 and 33 are stacked.

The resistance of the magnetoresistive effect element MTJ varies depending on the relative magnetization directions of a storage layer and a reference layer because of a magnetoresistive effect. For example, the resistance of the magnetoresistive effect element MTJ is low at the time of a parallel state in which the magnetization directions of the storage layer and the reference layer are the same, and is high at the time of an antiparallel state in which the magnetization directions of the storage layer and the reference layer are opposite to each other.

The first and second ferromagnetic layers 31 and 33 comprise, for example, CoFeB, MgFeO or a lamination of these. In the case of a magnetoresistive effect element having vertical magnetization, it is preferable that the first and second ferromagnetic layers 31 and 33 comprise TbCoFe having vertical magnetic anisotropy, an artificial lattice in which Co and Pt are stacked together, Llo-ordered FePt, etc. In this case, CoFeB as an interface layer may be provided between the first ferromagnetic layer 31 and the nonmagnetic insulating layer 32, or between the nonmagnetic insulating layer 32 and the second ferromagnetic layer 33.

The nonmagnetic insulating layer 32 comprises, for example, MgO or AlO. The nonmagnetic insulating layer 32 may be nitride of Al, Si, Be, Mg, Ca, Sr, Ba, Sc, Y, La, Zr, Hf, etc.

The first and second ferromagnetic layers 31 and 33 may each comprise a shift cancelling layer. The shift cancelling layer has a magnetization direction opposite to the magnetization direction of a reference layer. The shift cancelling layer thereby cancels a shift of a magnetization reversal characteristic (hysteresis curve) of a storage layer which occurs due to a stray magnetic field from the reference layer. It is preferable that the shift cancelling layer have, for example, a structure [Co/Pt]n in which n Co layers and Pt layers are stacked.

The above-described magnetoresistive effect element MTJ is pattered by IBE, for example, with the metal layer 13 used as a mask. This IBE is executed with the acceleration voltage of 200 V in the comparative example, and with the acceleration voltage higher than 200 V in the embodiment. An ion beam includes one of Ne, Ar, Kr, Xe, N₂ and O₂.

In this case, the magnetoresistive effect element MTJ formed by IBE of the comparative example has, for example, an aspect ratio H/D of 1.47. On the other hand, the magnetoresistive effect element MTJ formed by IBE of the embodiment has, for example, an aspect ration H/D higher than 1.47. This is mainly because a thickness t1 of the metal layer 13 after IBE is small in the comparative example, while a thickness t2 of the metal layer 13 after IBE is sufficiently large in the embodiment.

However, as shown in FIG. 7, H denotes the height of the magnetoresistive effect element MTJ in a direction in which the first and second ferromagnetic layers 31 and 33 are stacked, and D denotes the width of the nonmagnetic insulating layer 32 in the magnetoresistive effect element MTJ in a direction perpendicular to the direction in which the first and second ferromagnetic layers 31 and 33 are stacked.

It should be noted that the width of the nonmagnetic insulating layer 32 has been defined as D because the width of the nonmagnetic insulating layer 32 has an influence on the MR ratio of the magnetoresistive effect element 12 (MTJ).

Moreover, according to the embodiment, it is proved that as an acceleration voltage V_{IBE} becomes larger, an aspect ratio H/D becomes larger as shown in FIG. 8. For example, the aspect ratio H/D with the acceleration voltage V_{IBE} of 200 V is 1.47, the aspect ratio H/D with the acceleration voltage V_{IBE} of 300 V is 1.64, the aspect ratio H/D with the acceleration voltage V_{IBE} of 400 V is 1.72, and the aspect ratio H/D with the acceleration voltage V_{IBE} of 500 V is 1.75.

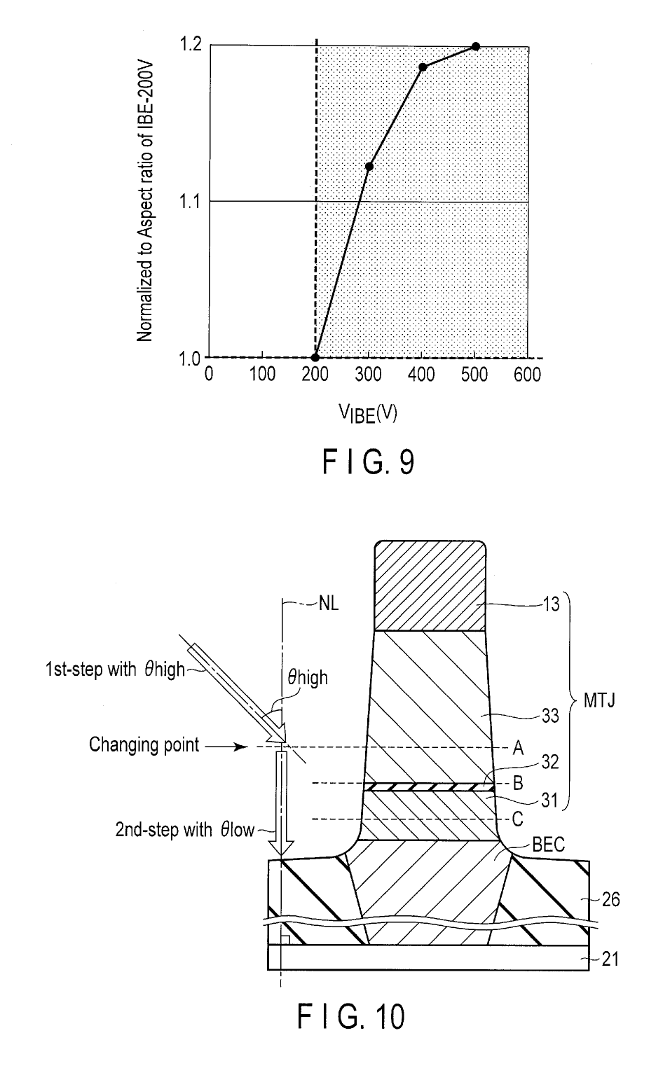

FIG. 9 shows normalized data of FIG. 8.

More specifically, the figure shows the aspect ratio H/D with the acceleration voltage V_{IBE} higher than 200 V in the case where the aspect ratio H/D with the acceleration voltage V_{IBE} of 200 V is 1.0.

As is clear from the figure, the aspect ratio H/D with the acceleration voltage V_{IBE} higher than 200 V is always higher than 1.0. That is, by making the acceleration voltage V_{IBE} of IBE higher than 200 V as in the embodiment, an aspect ratio H/D higher than in the conventional art (where the acceleration voltage V_{IBE} is 200 V) can be achieved.

In addition, as shown in FIG. 10, the magnetoresistive effect element MTJ can also be patterned by, for example, first etching using an ion beam at a beam angle θhigh of a first value (a value in the range of, for example, 30° to 89°, or more preferably, in the range of 30° to 60°) and second etching using an ion beam at a beam angle θlow of a second value (a value in the range of 0° to 30° less than the first value after the first etching.

Also in this case, the first and second etchings are executed by using an ion beam accelerated by an acceleration voltage higher than 200 V.

However, the beam angle θhigh/θlow is an angle between a direction NL in which the first and second ferromagnetic layers 31 and 33 in the magnetoresistive effect element MTJ are stacked (or a direction perpendicular to a top surface of the substrate 21) and a direction in which the ion beam is irradiated.

The first etching is executed under such a condition as prevents an etched material from being reattached to a sidewall of the magnetoresistive effect element MTJ. However, in the first etching, because of a so-called shadow effect, it is hard to carry out etching at a bottom portion of the magnetoresistive effect element MTJ, and the magnetoresistive effect element MTJ assumes a shape with its foot trailed. Thus, the bottom portion of the magnetoresistive effect element MTJ is etched by the second etching.

A changing point between the first etching and the second etching may be in the second ferromagnetic layer 33 (point A), or may be in the vicinity of the nonmagnetic insulating layer 32 (point B), and moreover, may be in the first ferromagnetic layer 31 (point C).

3. Method of Manufacturing Magnetic Memory

A method of manufacturing a magnetic memory comprising the magnetoresistive effect element of FIG. 10 will be described.

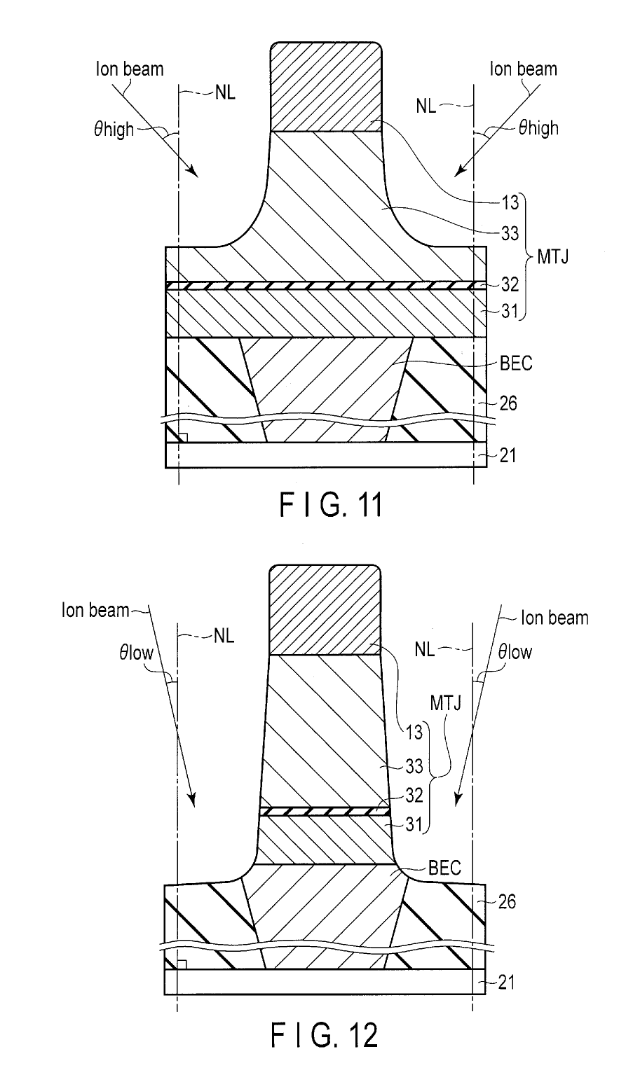

First, as shown in FIG. 11, a laminated structure of the first ferromagnetic layer 31, the nonmagnetic insulating layer 32, the second ferromagnetic layer 33 and the hard mask layer 13 are formed on the contact plug BEC in the interlayer insulating layer 26.

Then, a first etching process is executed.

The first etching process is executed by, for example, ion beam etching (IBE) using an ion beam at a high angle θhigh. In this example, the first etching process is stopped in a middle of the second ferromagnetic layer 33.

Next, as shown in FIG. 12, a second etching process is executed.

The second etching process is executed by, for example, IBE using an ion beam at a low angle θlow. The second etching process is executed until the interlayer insulating layer 26 to be the ground of the magnetoresistive effect element 12 (MTJ) is exposed.

This is because the magnetic memory comprises an array of magnetoresistive effect elements MTJ. That is, the magnetoresistive effect elements MTJ in the magnetic memory can be electrically separated from each other by etching the first ferromagnetic layer 31 to the end.

Then, a protective layer, an interlayer insulating layer, etc., are formed by a well-known method.

By the above-described manufacturing method, the magnetic memory comprising the magnetoresistive effect element MTJ of FIG. 10 is completed.

### 4. Etching Apparatus

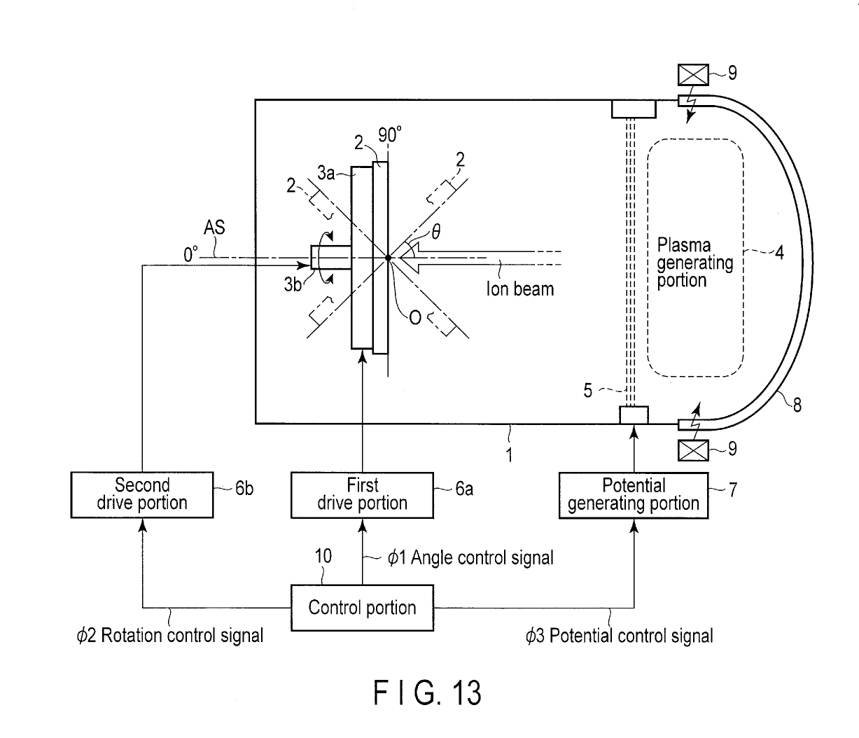

FIG. 13 shows an example of an IBE apparatus. An etching chamber 1 is, for example, a physical etching chamber for patterning an etching layer in a wafer 2 by IBE. The wafer 2 is, for example, a substrate on which a magnetic memory (an MRAM, etc.) is formed. A stage 3a is disposed in the etching chamber 1, and holds the wafer 2 including the etching layer. The stage 3a is supported by a support portion 3b.

A direction perpendicular to a top surface of the stage 3a (or a top surface of the wafer 2) can be inclined at e in a direction in which an ion beam is irradiated. That is, an angle θ between the direction perpendicular to the top surface of the stage 3a and the direction in which an ion beam is irradiated can be changed. This angle θ corresponds to a beam angle, and can be changed within a predetermined range of angles.

The example shows examples of the stage (solid line) 3a with a beam angle θ of 0° and the stage (broken line) 3a with a beam angle θ of 45°.

Moreover, the support portion 3b comprises an axis of rotation AS having its center at a point O. The axis of rotation AS is parallel to a direction in which an ion beam is irradiated, if the angle θ is 0°. The support portion 3b rotates, for example, with the stage 3a inclined at the angle θ. The stage 3a and the support portion 3b perform the function of causing the wafer 2 to rotate while an ion beam is irradiated. This rotation enables the wafer in-plane uniformity (σ) of an etching rate of the wafer 2 to be improved.

A plasma generating portion 4 is disposed in the etching chamber 1. The plasma generating portion 4 faces the stage 3a and generates ions from which an ion beam is generated. The plasma generating portion 4 is separated from the stage 3a by a grid 5.

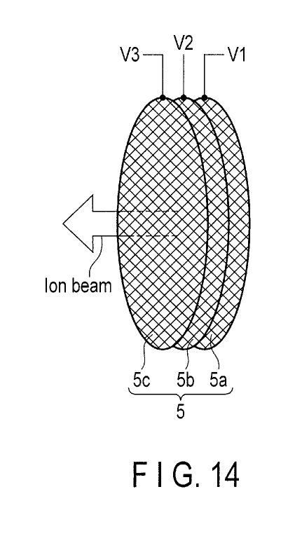

The grid 5 comprises first, second and third electrodes 5a, 5b and 5c as shown in FIG. 14. For example, an ion beam is generated by applying a positive potential V1 to the first electrode 5a, a negative potential V2 to the second electrode 5b and a ground potential V3 to the third electrode 5c, and drawing ions from the plasma generating portion 4 to the side of the wafer 2 through the grid 5. The ion beam includes, for example, one of Ne, Ar, Kr, Xe, N₂ and O₂.

A plasma power supply window 8 is, for example, an element for generating plasma by transmitting an electromagnetic wave (energy) from an antenna 9 to the plasma generating portion 4. The antenna 9 has a ring shape and surrounds the etching chamber 1.

A first drive portion 6a is a drive portion for adjusting the beam angle θ by rotating the stage 3a on the point O and changing the direction of the stage 3a. Also, a second drive portion 6b is a drive portion for rotating the stage 3a on the axis of rotation AS.

A potential generating portion 7 determines an acceleration voltage of ions used for IBE. For example, the potential generating portion 7 applies predetermined potentials to the first, second and third electrodes 5a, 5b and 5c of FIG. 14.

Further, a control portion 10 controls the first drive portion 6a, the second drive portion 6b and the potential generating portion 7.

### 5. Conclusion

As described above, according to the embodiment, an aspect ratio of a magnetic element can be increased by etching the magnetic element by IBE with the acceleration voltage of ions higher than 200 V. As a result, because the magnetic element can be prevented from being damaged at the time of etching for forming a contact hole for the magnetic element, the characteristics of the magnetic element can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory comprising:
a magnetic element; and
a metal layer stacked on the magnetic element,
wherein H/D>1.47 is satisfied, where H denotes a sum of thicknesses of the magnetic element and the metal layer in a first direction in which the magnetic element and the metal layer are stacked, and D denotes a width of the magnetic element in a second direction perpendicular to the first direction.

2. The memory of claim 1, wherein
the magnetic element includes a first ferromagnetic layer, a nonmagnetic insulating layer stacked on the first ferromagnetic layer, and a second ferromagnetic layer stacked on the nonmagnetic insulating layer.

3. The memory of claim 2, wherein
D denotes a width of the nonmagnetic insulating layer in the second direction.

4. The memory of claim 1, wherein
the metal layer includes one of W, Ta, Ru, Ti, TaN and TiN.

5. The memory of claim 1, further comprising:
an FET having a gate, a source, and a drain,
wherein the magnetic element is provided above the FET.

6. A method of manufacturing a magnetic memory, the method comprising:
forming a metal layer on a magnetic element;
patterning the metal layer; and
patterning the magnetic element by using an ion beam accelerated by an accelerating voltage of higher than 200 V after patterning the metal layer.

7. The method of claim 6, wherein
the ion beam includes one of Ne, Ar, Kr, Xe, N₂ and O₂.

8. The method of claim 6, wherein
the patterning the magnetic element includes a first etching and a second etching after the first etching.

9. The method of claim 8, wherein
the first etching is executed by a beam angle larger than a beam angle of the second etching.

10. The method of claim 9, wherein
the beam angle of the first etching is selected to be in a range of 30° to 60°, where the beam angle is an angle between a direction in which the magnetic element and the metal layer are stacked and a direction in which the ion beam is irradiated.

11. The method of claim 9, wherein
the beam angle of the second etching is selected to be in a range of 0° to 30°, where the beam angle is an angle between a direction in which the magnetic element and the metal layer are stacked and a direction in which the ion beam is irradiated.

12. The method of claim 8, wherein
the magnetic element is formed by forming a nonmagnetic insulating layer on a first ferromagnetic layer, and forming a second ferromagnetic layer on the nonmagnetic insulating layer.

13. The method of claim 12, wherein
a changing point between the first and second etchings is provided in the second ferromagnetic layer.

14. The method of claim 12, wherein
a changing point between the first and second etchings is provided on the nonmagnetic insulating layer.

15. The method of claim 12, wherein
a changing point between the first and second etchings is provided in the first ferromagnetic layer.

16. The method of claim 6, wherein
the metal layer includes one of W, Ta, Ru, Ti, TaN and TiN.

17. The method of claim 6, wherein
the metal layer is patterned by one of RIE and IBE.

18. The method of claim 6, further comprising:
forming an FET having a gate, a source, and a drain,
wherein the magnetic element is formed above the FET.
